(19) United States
(12) Patent Application Publication
(10) Pub. No.: US 2026/0106603 A1
(43) Pub. Date: Apr. 16, 2026

(54) Driving High Speed Voltage Waveforms for Current Measurements

(71) Applicant: NATIONAL INSTRUMENTS CORPORATION, Austin, TX (US)

(72) Inventors: John George Banaska, Spicewood, TX (US); Lauren R. Sjoboen, Round Rock, TX (US); Eric Hartner, Apex, NC (US)

(21) Appl. No.: 19/355,665

(22) Filed: Oct. 10, 2025

Related U.S. Application Data
(60) Provisional application No. 63/706,115, filed on Oct. 11, 2024.

(51) Int. Cl. H03K 3/0232; G01R 31/3163; H03K 3/011; H03K 3/57

(52) U.S. Cl. CPC H03K 3/0232; G01R 31/3163; H03K 3/011; H03K 3/57

(57) ABSTRACT

Apparatuses, systems, and methods for, and more particularly to apparatuses, systems, and methods for a high-speed composite amplifier driving circuit to generate and output analog signals. The high-speed composite amplifier driving circuit can combine a voltage-controlled pulser and waveform generator with high-accuracy current-voltage (I-V) measurement functions. The voltage-controlled pulser and waveform generator, for example, can provide a ±5 volt, 10 milliamp waveform at up to 50 megahertz with 5 nanosecond rise/fall timing and 8 ns minimum pulse widths. In addition, the high-accuracy I-V measurements can measure a ±10 volts, 10 milliamp waveform at up to 30 MHz with 7-10 nanosecond rise/fall timing and 8 to 12 nanosecond minimum pulse widths.

### PRIORITY CLAIM

This application claims benefit of priority to provisional application number 63/706,115 entitled “Driving High Speed Voltage Waveforms for Current Measurements”, filed on Oct. 11, 2024, whose disclosure is hereby incorporated by reference in its entirety as though fully and completely set forth herein.

### TECHNICAL FIELD

The invention relates to analog signal generation, and more particularly to apparatuses, systems, and methods for a high-speed composite amplifier driving circuit to generate analog signals.

### DESCRIPTION OF THE RELATED ART

Performing current or voltage measurement at any point along a voltage pulse or arbitrarily generated voltage waveform has long been a highly desired measurement capability. For such measurement applications, not only are direct current (DC) versus voltage (IV) characteristics required, but also alternating current (AC) characteristics (such as pulsed IV, stepped IV or ramped IV) are required for accurate characterization. Additionally, the ability to perform noise current analysis in both the time and frequency domains continues to take on increased importance for advanced device characterization in a variety of applications.

Current solutions, like a waveform generator/fast measurement unit (WGFMU), use a current to voltage converter to drive an output and measure a current going to the output at the same time. However, this leads to reduced bandwidth and increased settling time as the current range decreases, e.g., because a resistance driving the output increases one-to-one with increased current sensitivity. Therefore, improvements are desirable.

### SUMMARY

Embodiments described herein relate to analog signal generation and output, and more particularly to apparatuses, systems, and methods for a high-speed composite amplifier driving circuit to generate and output analog signals. The high-speed composite amplifier driving circuit can combine a voltage-controlled pulser and waveform generator with high-accuracy current-voltage (I-V) measurement functions. The voltage-controlled pulser and waveform generator, for example, can provide a ±5 volt, 10 milliamp waveform at up to 50 megahertz (MHz) with 5 nanosecond (ns) rise/fall timing and 8 ns minimum pulse widths. In addition, the high-accuracy I-V measurements can measure a ±10V, 10 milliamp waveform at up to 30 MHz with 7-10 ns rise/fall timing and 8-12 ns minimum pulse widths.

As an example, in some embodiments, a circuit and/or a remote test head can include a first input, a first resistor connected in series with the first input, a first capacitor connected to an output of the first resistor, wherein the first capacitor is further connected to a ground, a driver comprising a positive input, a negative input, and an output, wherein the positive input is connected in series with the first resistor, a second resistor connected to the output of the driver, a second capacitor in parallel with the second resistor, and a feedback loop that comprises at least the second resistor and second capacitor. The first capacitor can be configured to compensate for an underdamped response of a waveform signal applied to the first input. In addition, the second capacitor can be configured to compensate for an overdamped response of the waveform signal applied to the first input.

As another example, in some embodiments, a circuit and/or remote test head can include a first port configured to accept a first analog signal from an arbitrary waveform generator, a second port configured to interface with an oscilloscope, a third port configured to interface with a device under test, a fourth port configured to interface with a power supply and a controller, first circuitry, and second circuitry. The first circuitry can include at least a first driver that can be configured to drive a second analog signal, based, at least in part, on the first analog signal, for voltage measurement and current measurement of the device under test. The second circuitry can include at least a second driver that can be configured to drive a third analog signal to a boot node for powering the first circuitry in a bootstrapping manner. The boot node can operate as a floating power supply. The third analog signal can be based, at least in part, on the first analog signal.

As a further example, in some embodiments, a circuit and/or a remote test head can include a first port configured to accept a first analog signal from an arbitrary waveform generator, a second port configured to interface with an oscilloscope, a third port configured to interface with a device under test, a fourth port configured to interface with a power supply and a controller, and first circuitry. The first circuitry can include at least a first driver and a differential amplifier. The first driver can be configured to drive a second analog signal, based, at least in part on the first analog signal, for voltage measurement and current measurement of the device under test. The differential amplifier can be connected to a ground (e.g., a ground reference) and configured to translate a volage across the differential amplifier back to a measurement reference voltage.

As a yet further example, in some embodiments, a circuit and/or remote test head can include a first input, a first resistor connected in series with the first input, a driver, and a second resistor connected in series to the output of the driver. The driver can include a positive input, a negative input, an output. The positive input can be connected in series with the first resistor. In addition, the second resistor can be positioned inside a driver feedback loop that connects to the negative input of the driver. Further, the second resistor can be a sensing resistor configured for current measurements on a device under test connected to an output of the circuit.

As yet another example, in some embodiments, a circuit and/or remote test head can include a first input, a first resistor connected in series with the first input, a driver, a second resistor connected in series to an output of the driver, and a first high speed amplifier placed in series between the output of the driver and the second resistor. A feedback loop of the high speed amplifier can be closed around the second resistor.

As an additional example, in some embodiments, a circuit and/or remote test head can include a first port configured to accept a first analog signal from an arbitrary waveform generator, a second port configured to interface with an oscilloscope, a third port configured to interface with a device under test, a fourth port configured to interface with a power supply and a controller, and circuitry comprising at least a driver and a first high speed amplifier. The driver can be configured to drive a second analog signal, based, at least in part on the first analog signal, for voltage measurement and current measurement of the device under test. In addition, the high speed amplifier can be connected in series between the driver and a sensing resistor and a feedback loop of the high speed amplifier can be closed around the sensing resistor.

Note that the techniques described herein may be implemented in and/or used with a number of different types of systems, including but not limited to Peripheral Component Interconnect (PCI) DAQ devices, compact PCI DAQ devices, universal serial bus (USB) DAQ devices, various DAQ chassis, and any of various other computing devices.

This Summary is intended to provide a brief overview of some of the subject matter described in this document. Accordingly, it will be appreciated that the above-described features are only examples and should not be construed to narrow the scope or spirit of the subject matter described herein in any way. Other features, aspects, and advantages of the subject matter described herein will become apparent from the following Detailed Description, Figures, and Claims.

### BRIEF DESCRIPTION OF THE DRAWINGS

A better understanding of the disclosed embodiments can be obtained when the following detailed description of the preferred embodiments is considered in conjunction with the following drawings.

FIG. 1 illustrates an example of a computer system, according to some embodiments.

FIG. 2 illustrates an example block diagram of a server 104, according to some embodiments.

FIG. 3 illustrates an example block diagram of a circuit for current measurement, according to some embodiments.

FIG. 4 illustrates an example block diagram of a circuit for current measurement with device under test (DUT) isolation, according to some embodiments.

FIG. 5 illustrates an example block diagram of a circuit for current measurement with compensation for DUT isolation, according to some embodiments.

FIG. 6 illustrates an example block diagram of a circuit for current measurement with compensation for DUT isolation and 1 milliamp and 10 milliamp ranges, according to some embodiments.

FIG. 7 illustrates another example block diagram of a circuit for current measurement with compensation for DUT isolation and 1 milliamp and 10 milliamp ranges, according to some embodiments.

FIG. 8 illustrates an example block diagram of a circuit for current measurement with compensation for DUT isolation, 1 milliamp and 10 milliamp ranges, and tuning, according to some embodiments.

FIG. 9 illustrates an example block diagram of a circuit for current measurement with compensation for DUT isolation, 1 milliamp and 10 milliamp ranges, tuning, and power supply, according to some embodiments.

FIG. 10 illustrates an example block diagram of a circuit for current measurement with compensation for DUT isolation, 1 milliamp and 10 milliamp ranges, tuning, power supply, and calibration, according to some embodiments.

FIG. 11 illustrates an example of a simplified block diagram of a circuit for current measurement, according to some embodiments.

While the features described herein may be susceptible to various modifications and alternative forms, specific embodiments thereof are shown by way of example in the drawings and are herein described in detail. It should be understood, however, that the drawings and detailed description thereto are not intended to be limiting to the particular form disclosed, but on the contrary, the intention is to cover all modifications, equivalents and alternatives falling within the spirit and scope of the subject matter as defined by the appended claims.

### DETAILED DESCRIPTION

### Acronyms

Various acronyms are used throughout the present disclosure. Definitions of the most prominently used acronyms that may appear throughout the present disclosure are provided below:
DAQ: Data Acquisition
DUT: Device Under Test
UUT: Unit Under Test
GUI: Graphical User Interface
I-V: Current-Voltage

### Terms

The following is a glossary of terms used in this disclosure:

Device Under Test (DUT) or Unit Under Test (UUT)—A physical device or component that is being tested.

Slew Rate or Analog Slew Rate—A maximum rate at which an amplifier's output can change when an input signal moves from a minimum output level to a maximum output level. Slew rate is considered an indicator as to how well an amplifier can reproduce all frequencies and amplitudes for dynamic content. For example, when an amplifier's slew rate is too low, an output signal can reflect the slew rate's behavior instead of the expected output signal. This can be referred to as slew-rate-limited behavior with the output appearing as a linear ramp with a slope equal to the slew rate. Note that slew rate is related to bandwidth and can be controlled by internal compensation. Slew rate limit is typically set by a current available to charge or discharge an amplifier's capacitance and/or a connected output load.

Memory Medium—Any of various types of non-transitory memory devices or storage devices. The term “memory medium” is intended to include an installation medium, e.g., a CD-ROM, floppy disks, or tape device; a computer system memory or random-access memory such as DRAM, DDR RAM, SRAM, EDO RAM, Rambus RAM, etc.; a non-volatile memory such as a Flash, magnetic media, e.g., a hard drive, or optical storage; registers, or other similar types of memory elements, etc. The memory medium may include other types of non-transitory memory as well or combinations thereof. In addition, the memory medium may be located in a first computer system in which the programs are executed, or may be located in a second different computer system which connects to the first computer system over a network, such as the Internet. In the latter instance, the second computer system may provide program instructions to the first computer for execution. The term “memory medium” may include two or more memory mediums which may reside in different locations, e.g., in different computer systems that are connected over a network. The memory medium may store program instructions (e.g., embodied as computer programs) that may be executed by one or more processors.

Carrier Medium—a memory medium as described above, as well as a physical transmission medium, such as a bus, network, and/or other physical transmission medium that conveys signals such as electrical, electromagnetic, or digital signals.

Programmable Hardware Element—includes various hardware devices comprising multiple programmable function blocks connected via a programmable interconnect. Examples include FPGAs (Field Programmable Gate Arrays), PLDs (Programmable Logic Devices), FPOAs (Field Programmable Object Arrays), and CPLDs (Complex PLDs). The programmable function blocks may range from fine grained (combinatorial logic or look up tables) to coarse grained (arithmetic logic units or processor cores). A programmable hardware element may also be referred to as “reconfigurable logic”.

Computer System (or Computer)—any of various types of computing or processing systems, including a personal computer system (PC), mainframe computer system, workstation, network appliance, Internet appliance, personal digital assistant (PDA), television system, grid computing system, or other device or combinations of devices. In general, the term “computer system” can be broadly defined to encompass any device (or combination of devices) having at least one processor that executes instructions from a memory medium.

Processing Element (or Processor)—refers to various elements or combinations of elements that are capable of performing a function in a device, such as a user equipment or a cellular network device. Processing elements may include, for example: processors and associated memory, portions or circuits of individual processor cores, entire processor cores, processor arrays, circuits such as an ASIC (Application Specific Integrated Circuit), programmable hardware elements such as a field programmable gate array (FPGA), as well any of various combinations of the above.

Program—the term “program” is intended to have the full breadth of its ordinary meaning. The term “program” includes 1) a software program which may be stored in a memory and is executable by a processor or 2) a hardware configuration program useable for configuring a programmable hardware element.

Software Program—the term “software program” is intended to have the full breadth of its ordinary meaning, and includes any type of program instructions, code, script and/or data, or combinations thereof, that may be stored in a memory medium and executed by a processor. Exemplary software programs include programs written in text-based programming languages, such as C, C++, Pascal, Fortran, Cobol, Java, assembly language, etc.; graphical programs (programs written in graphical programming languages); assembly language programs; programs that have been compiled to machine language; scripts; and other types of executable software. A software program may comprise two or more software programs that interoperate in some manner.

Automatically—refers to an action or operation performed by a computer system (e.g., software executed by the computer system) or device (e.g., circuitry, programmable hardware elements, ASICs, etc.), without user input directly specifying or performing the action or operation. Thus, the term “automatically” is in contrast to an operation being manually performed or specified by the user, where the user provides input to directly perform the operation. An automatic procedure may be initiated by input provided by the user, but the subsequent actions that are performed “automatically” are not specified by the user, i.e., are not performed “manually”, where the user specifies each action to perform. For example, a user filling out an electronic form by selecting each field and providing input specifying information (e.g., by typing information, selecting check boxes, radio selections, etc.) is filling out the form manually, even though the computer system must update the form in response to the user actions. The form may be automatically filled out by the computer system where the computer system (e.g., software executing on the computer system) analyzes the fields of the form and fills in the form without any user input specifying the answers to the fields. As indicated above, the user may invoke the automatic filling of the form, but is not involved in the actual filling of the form (e.g., the user is not manually specifying answers to fields but rather they are being automatically completed). The present specification provides various examples of operations being automatically performed in response to actions the user has taken.

Approximately—refers to a value that is almost correct or exact. For example, approximately may refer to a value that is within 1 to 10 percent of the exact (or desired) value. It should be noted, however, that the actual threshold value (or tolerance) may be application dependent. For example, in some embodiments, “approximately” may mean within 0.1% of some specified or desired value, while in various other embodiments, the threshold may be, for example, 2%, 3%, 5%, and so forth, as desired or as required by the particular application.

Concurrent—refers to parallel execution or performance, where tasks, processes, or programs are performed in an at least partially overlapping manner. For example, concurrency may be implemented using “strong” or strict parallelism, where tasks are performed (at least partially) in parallel on respective computational elements, or using “weak parallelism”, where the tasks are performed in an interleaved manner, e.g., by time multiplexing of execution threads.

Various components may be described as “configured to” perform a task or tasks. In such contexts, “configured to” is a broad recitation generally meaning “having structure that” performs the task or tasks during operation. As such, the component can be configured to perform the task even when the component is not currently performing that task (e.g., a set of electrical conductors may be configured to electrically connect a module to another module, even when the two modules are not connected). In some contexts, “configured to” may be a broad recitation of structure generally meaning “having circuitry that” performs the task or tasks during operation. As such, the component can be configured to perform the task even when the component is not currently on. In general, the circuitry that forms the structure corresponding to “configured to” may include hardware circuits.

Various components may be described as performing a task or tasks, for convenience in the description. Such descriptions should be interpreted as including the phrase “configured to.” Reciting a component that is configured to perform one or more tasks is expressly intended not to invoke 35 U.S.C. § 112(f) interpretation for that component.

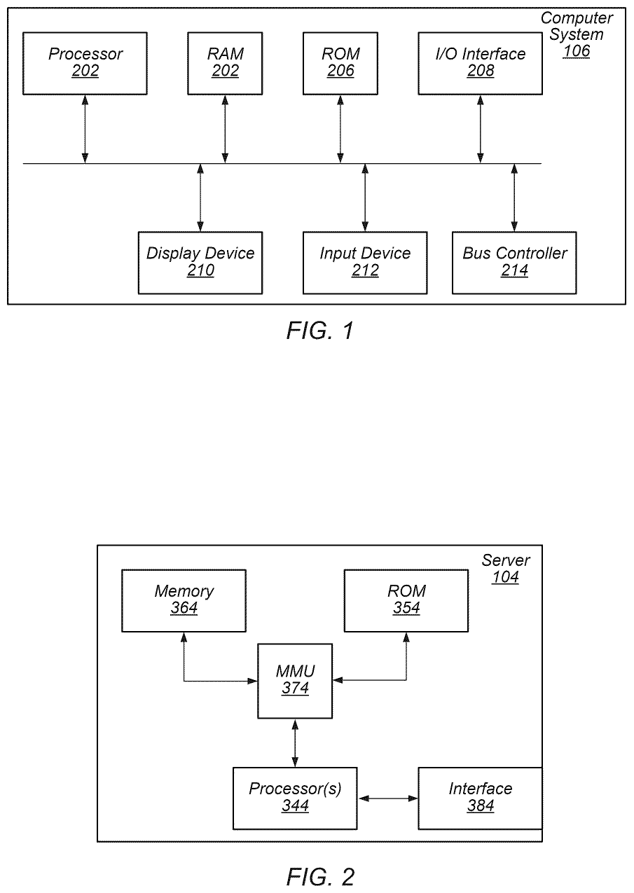

### FIG. 1: Computer System

FIG. 1 illustrates a computer system 106 that may include a processor 202, random access memory (RAM) 204, nonvolatile memory 206, a display device 210, an input device 212, an I/O interface 208 (e.g., such as a universal serial bus (USB) for coupling to sensors, and a bus controller 214, e.g., for interfacing/connecting to an expansion bus, such as a PCI (Peripheral Component Interconnect) expansion bus, among other examples of buses. For example, the computer system 106 may include hardware and software components for implementing or supporting implementation of features described herein. The processor 202 may be configured to implement or support implementation of part or all of the methods described herein, e.g., by executing program instructions stored on a memory medium (e.g., a non-transitory computer-readable memory medium). Alternatively, the processor 202 may be configured as a programmable hardware element, such as an FPGA (Field Programmable Gate Array), or as an ASIC (Application Specific Integrated Circuit), or a combination thereof. Alternatively (or in addition) the processor 202, in conjunction with one or more of the other components 204, 206, 208, 210, 212, and/or 214 may be configured to implement or support implementation of part or all of the features described herein.

In addition, as described herein, processor(s) 202 may be comprised of one or more processing elements. In other words, one or more processing elements may be included in processor(s) 202. Thus, processor(s) 202 may include one or more integrated circuits (ICs) that are configured to perform the functions of processor(s) 202. In addition, each integrated circuit may include circuitry (e.g., first circuitry, second circuitry, etc.) configured to perform the functions of processor(s) 202.

As shown, the computer system 106 may include a processor that is coupled to a random access memory (RAM) and a nonvolatile memory. The computer system 106 may also include user interface elements for receiving user input and a display device for presenting output. For example, the user interface elements may include any of various elements, such as a display (which may be a touchscreen display), a keyboard (which may be a discrete keyboard or may be implemented as part of a touchscreen display), a mouse, a microphone and/or speakers, one or more cameras, one or more buttons, and/or any of various other elements capable of providing information to a user and/or receiving or interpreting user input. The computer system 106 may also include an Input/Output (I/O) interface that may be communicatively coupled (e.g., locally via a system bus, or remotely via a network and/or serial interface) to various hardware elements (e.g., such as FPGAs, data acquisition boards, controllers, and the like).

### FIG. 2: Server

FIG. 2 illustrates an example block diagram of a server 104, according to some embodiments. It is noted that the server of FIG. 2 is merely one example of a possible server. As shown, the server 104 may include processor(s) 344 which may execute program instructions for the server 104. The processor(s) 344 may also be coupled to memory management unit (MMU) 374, which may be configured to receive addresses from the processor(s) 344 and translate those addresses to locations in memory (e.g., memory 364 and read only memory (ROM) 354) or to other circuits or devices.

The server 104 may be configured to provide a plurality of devices, such as computer system 106, access to various DAQ devices, e.g., via interface (e.g., network interface) 384.

In some embodiments, the server 104 may be accessed via a radio access network via interface 384, such as a 5G New Radio (5G NR) radio access network. In some embodiments, the server 104 may be accessed via a local area network (LAN), e.g., via an ethernet and/or Wi-Fi connection (e.g., supported by interface 384).

As described further subsequently herein, the server 104 may include hardware and software components for implementing or supporting implementation of features described herein. The processor 344 of the server 104 may be configured to implement or support implementation of part or all of the methods described herein, e.g., by executing program instructions stored on a memory medium (e.g., a non-transitory computer-readable memory medium). Alternatively, the processor 344 may be configured as a programmable hardware element, such as an FPGA (Field Programmable Gate Array), or as an ASIC (Application Specific Integrated Circuit), or a combination thereof. Alternatively (or in addition) the processor 344 of the server 104, in conjunction with one or more of the other components 354, 364, and/or 374 may be configured to implement or support implementation of part or all of the features described herein.

In addition, as described herein, processor(s) 344 may be comprised of one or more processing elements. In other words, one or more processing elements may be included in processor(s) 344. Thus, processor(s) 344 may include one or more integrated circuits (ICs) that are configured to perform the functions of processor(s) 344. In addition, each integrated circuit may include circuitry (e.g., first circuitry, second circuitry, etc.) configured to perform the functions of processor(s) 344.

### Analog Signal Generation and Output

In existing implementations, a waveform generator/fast measurement unit (WGFMU) uses a current to voltage converter to drive an output and measure a current going to the output at the same time. However, this leads to reduced bandwidth and increased settling time as the current range decreases, e.g., because a resistance driving the output increases one-to-one with increased current sensitivity.

In addition, devices with an output impedance near zero must keep a transmission line short when driving high speed signals and/or signals with high analog slew rates to keep a lumped element system, where tpd=˜⅙^{th} to 1/20^{th} the signal rise time. Alternatively, such devices can have a 50Ω output impedance. However, while this functions as a superb transmission line solution, it suffers from a “line load” voltage drop across a source matching resistor and, in the case of a device under test (DUT) with a varying load impedance, an actual voltage across the DUT is varying and mostly indeterminable without knowing the current or the impedance. Therefore, improvements are desirable.

Embodiments described herein provide systems, methods, and mechanisms for analog signal generation and output, and more particularly to apparatuses, systems, and methods for a high-speed composite amplifier driving circuit to generate and output analog signals. For example, embodiments described herein can remove non-idealities via a high-speed composite amplifier driving circuit to generate analog signals to an output, such as zero aberration square waves. Hence, embodiments described herein can provide, among other advantages, independent analog slew rate and aberration controls, binary weighted analog control of slew rate (and/or bandwidth), binary weighted analog control of squarewave overshoot/undershoot without impacting/changing analog slew rate, a low noise plus/minus 10 volt output drive, removal of slow measurement circuitry when driving fast signals via switching, driving of high speed analog signals via low voltage operation amplifiers with bootstrapping, translation of measurements back to a measurement reference via a differential amplifier to ground connection, as well as a synchronous analog waveform to digital engine and communication interface. As another example, embodiments described herein can compensate for a line load drop by applying a scaled, positive feedback, voltage to an output to compensate for a drop across an output resistor. Thus, embodiments described herein can provide, among other advantages, a calibrated positive feedback, compensation for transmission line matching resistor, as well as a synthetic zero ohm output impedance.

In some instances, to generate an analog signal in a 10 milliamp and/or 1 milliamp current range, current can be measured in line with an output stage without significantly impacting an output waveform. Further, direct current (DC) accuracy can be achieved by wrapping output resistance in an amplifier feedback loop. In addition, for lower current ranges (e.g., 1 milliamp range), where a larger sense resistor is required, at a transition from a high slew rate ‘stress’ signal to a lower slew rate measurement signal, measurement circuitry, which has been monitoring the output so it is already charged to the same voltage minimizing settling time, can be switched into the circuit, e.g., to both drive the output and measure the current. Note that since high quality measurement circuitry needs to be low noise, measurement circuitry is necessarily low bandwidth and require low voltage rails, the voltage rails are lower than the required output voltage. Thus, amplifiers can be boot strapped, e.g., their supply voltage rails can be driven by a buffered version of the input signal. This results in a power supply and measurement stage hovering around 6000 volts per microsecond to keep up with the input signal. Further, the output signal edge rate and overshoot can be adjusted to provide square wave output signals without aberration, e.g., via adjustment of an analog slew rate and peaking controls which are binary weighted for maximum effectiveness and resolutions.

In some instances, since some parts/elements in an output path can have a variable resistance due to time, temperature, and/or part to part (element to elements) variation, a binary weighted scaling adjustment can be added to a positive feedback loop. Such a scheme can allow an output to be calibrated to 0Ω +/−100 mΩ. Note that such a correction can work all the way up to a bandwidth of the positive feedback loop. Additionally, above the bandwidth of the feedback loop, the resistance takes over and can provide improved return loss in systems where a length of an output cable is near or above a transmission line critical length.

In some instances, a remote head can be configured to work with (e.g., interface and/or communication with) an arbitrary waveform generator (AWG) and an oscilloscope. The AWG can drive a voltage into the remote head (e.g., in a first mode of operation, e.g., “fast IV” mode). The remote head can amplify the voltage and drive the voltage to a device under test (DUT). The voltage can be carried to the DUT via an 8 inch 50 ohm coax cable, at least in some instances. In addition, the DUT can have a capacitance as low as 0 pico Farads (pF) up to 1 nano Farad (nF), however, at least in some instances, the remote head can be configured for DUT capacitance ranging from 0 pF up to 30 pF to ensure optimal performance. The range of the voltage driven to the DUT by the remote head can vary up to ±10V. In addition, the remote head can be configured to have a voltage rise time to an edge of less than 12 nano seconds (nS).

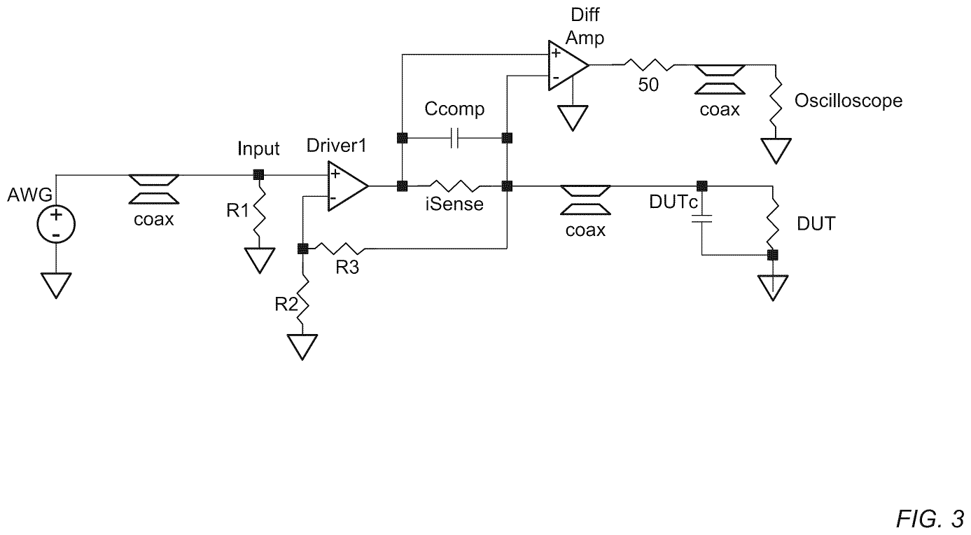

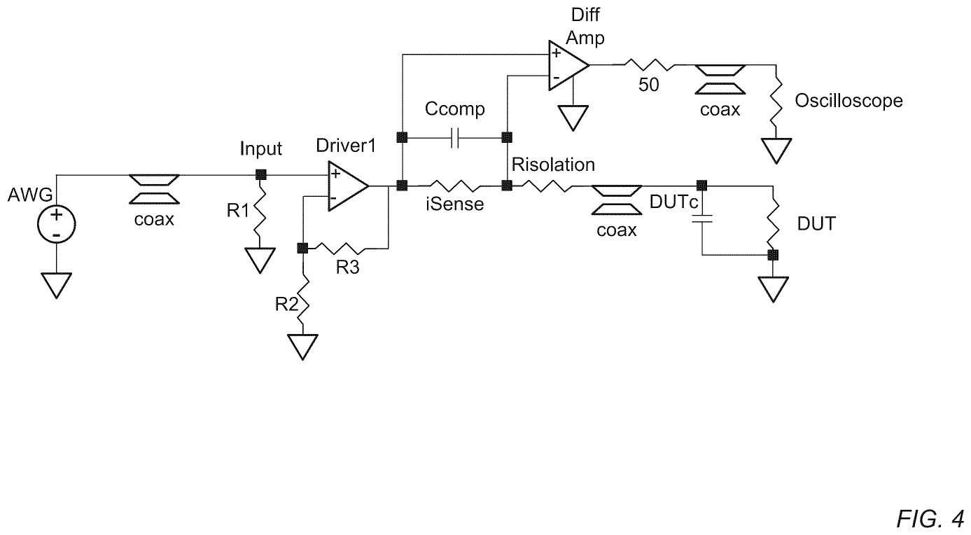

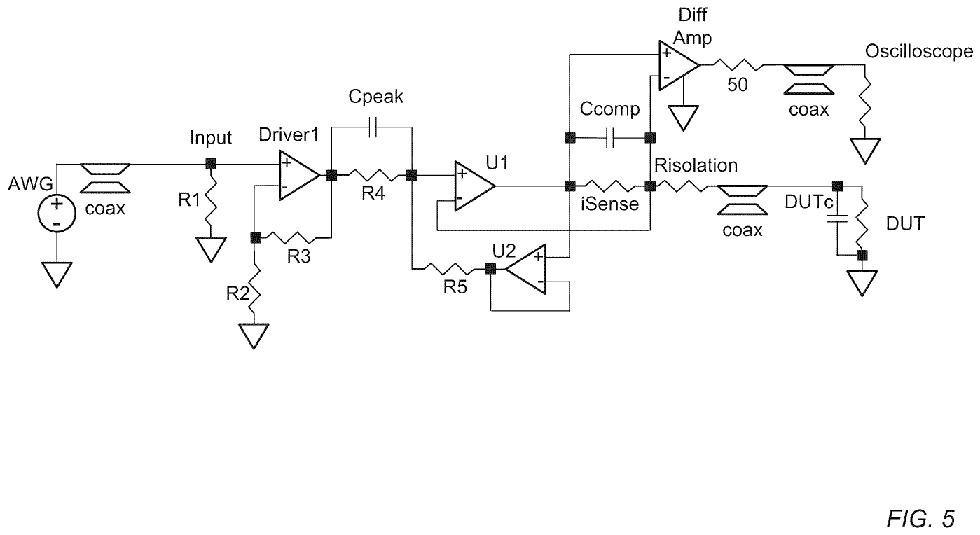

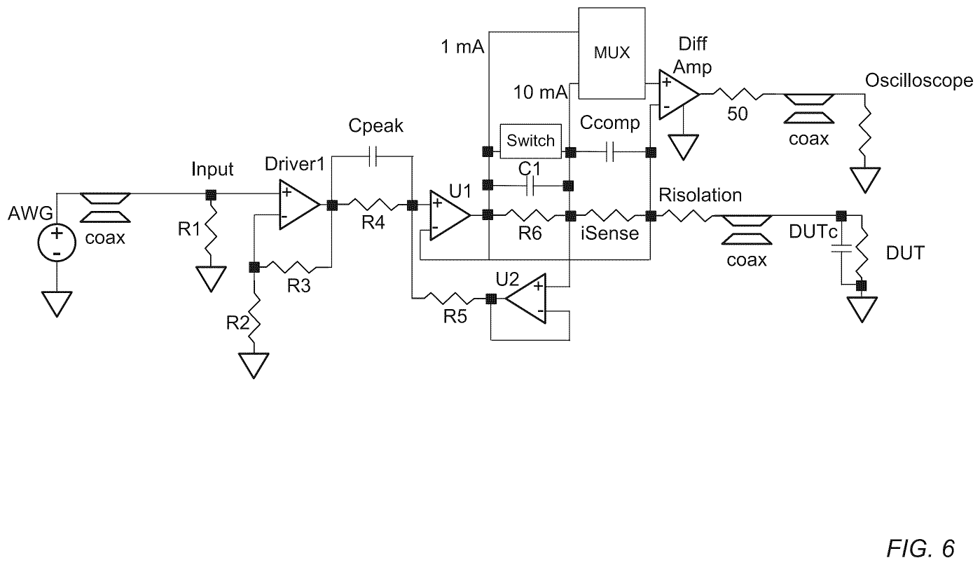

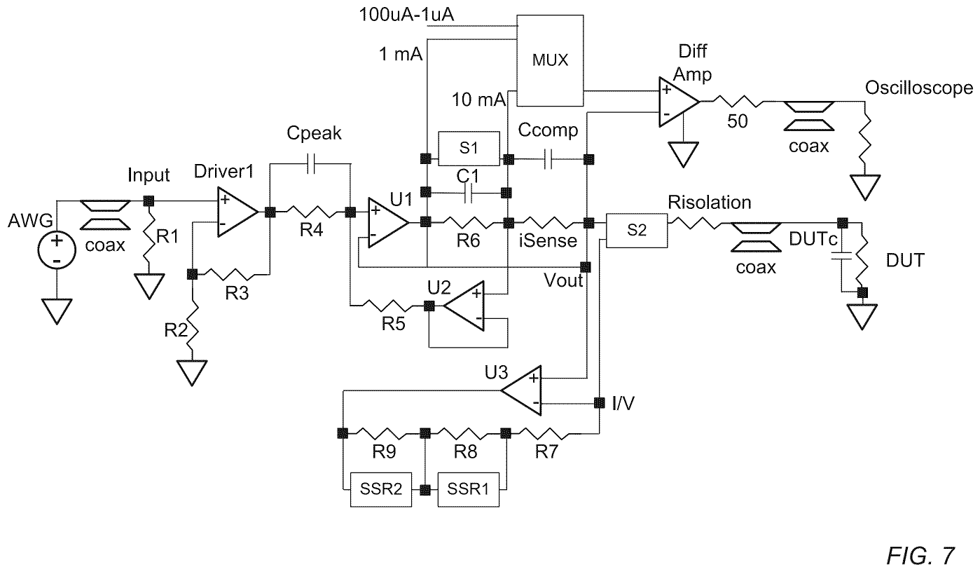

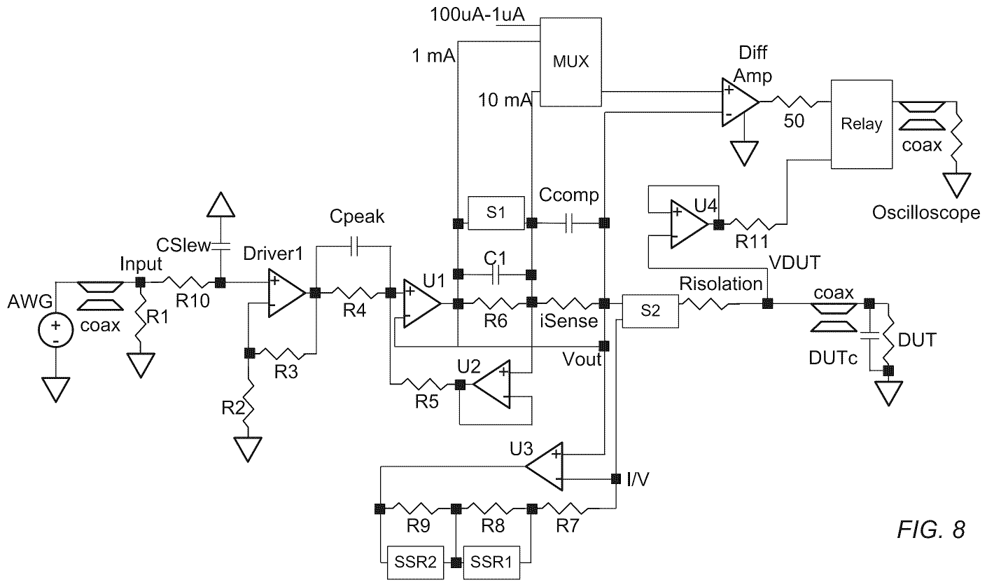

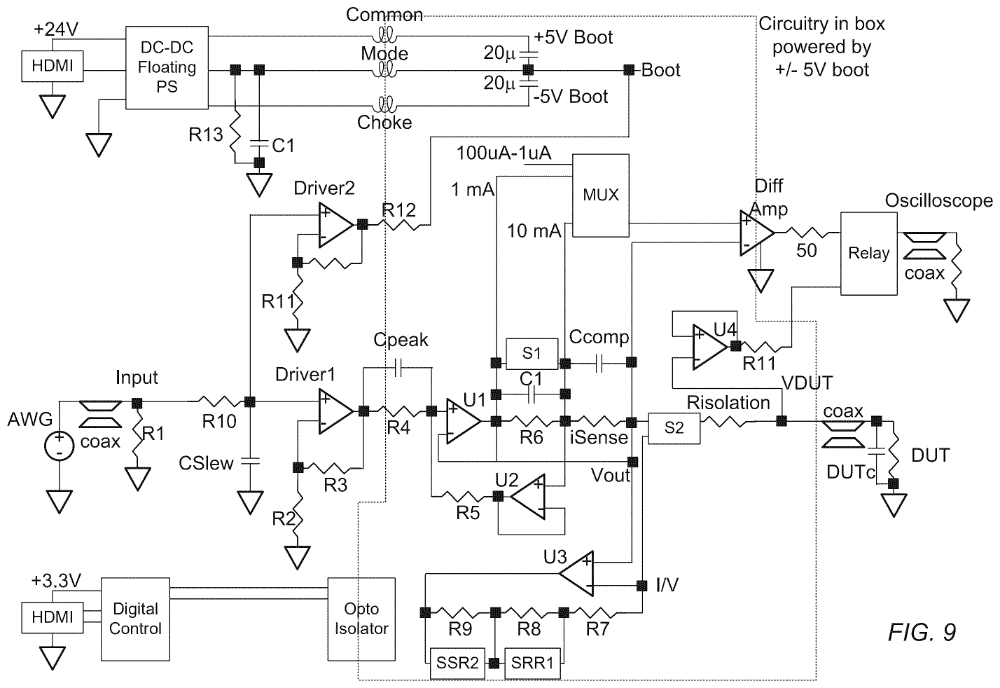

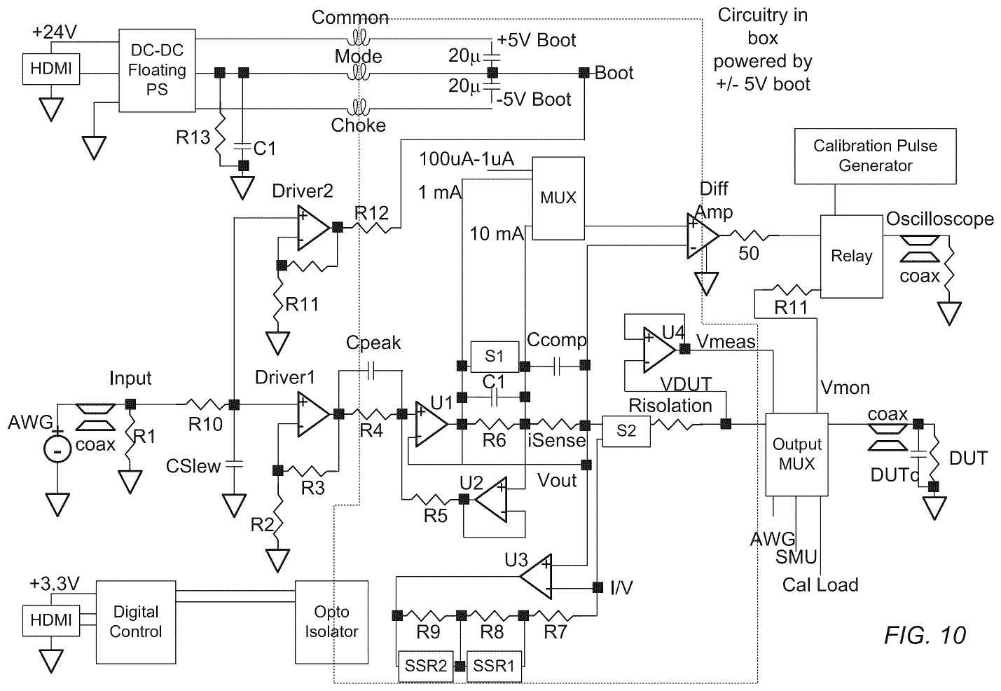

FIGS. 3-10 illustrate examples of various circuits of a remote test head, according to some embodiments. As will become evident from the descriptions, the circuit of FIG. 3 can serve as a “building block” for the circuit of FIG. 4 which can serve as a “building block” for the circuit of FIG. 5. Additionally, the circuit of FIG. 5 can serve as a “building block” for the circuit of FIG. 6 which can serve as a “building block” for the circuit of FIG. 7. Further, the circuit of FIG. 7 can serve as a “building block” for the circuit of FIG. 8 which can serve as a “building block” for the circuit of FIG. 9. Finally, the circuit of FIG. 9 can server as a “building block” for the circuit of FIG. 10. Thus, elements described in a preceding Figure can be applicable to the description of elements in the foregoing Figures. Note that the circuits described in reference to FIGS. 3-10 can be used in conjunction with the above described computer system 106 and/or server 104. For example, in some instances, software executing on computer system 106 and/or sever 104 can be used to control the circuits described in reference to FIGS. 3-10.

For example, FIG. 3 illustrates an example block diagram of a circuit for current measurement, according to some embodiments. As shown, the circuit can include connection points for a waveform generator, denoted as “ARB” (e.g., arbitrary waveform generator), an oscilloscope, and a device under test (DUT). The waveform generator, oscilloscope, and DUT can be connected via wiring, e.g., such as coaxial (“coax”) cabling. The wiring for the waveform generator, oscilloscope, and DUT can each have a particular resistance and/or impedance. The waveform generator can attach to the circuit at the input, as shown. Resistor R1 can attach the input to ground. Resistor R1 can, for example, be a 50 ohm resistor. The input from the waveform generator can feed into a driver (e.g., Driver 1). The driver can be a high speed driver. Further, to facilitate current measurement, a sensing resistor, Isense, can be placed in series with an output driver and inside a driver feedback loop to maintain zero ohm output impedance. The driver feedback loop can include resistors R2 and R3, as shown. In some instances, R2 can have a resistance of 357 ohms, for example. In some instances, R3 can have a resistance of 1230 ohms, for example, The driver can combine the input with a signal from the driver feedback loop. In addition, as shown, a high speed common-mode rejection ratio (CMRR) differential amplifier can function as the output driver. The output driver can sense across the sensing resistor and translate the signal back to ground. A divider, using an oscilloscope in 50 ohm input, can be used to measure current. In some instances, five ranges of current can be required, from 10 milliamps to 1 microamp. Thus, at 200 millivolts full scale, the sensing resistor can be in a range of 20 ohms to 200,000 ohms. Further, current settling time requirements can range from 125 nanosecond for 10 milliamp range to 6 microseconds for 1 microamp range. In turn, the compensation capacitance, Ccomp, across the sensing resistor ends up around 5 picofarads.

In some instances, the output driver can be a 6000 volts per microsecond 300 MHz amplifier. However, 5 picofarads capacitance may not be able to keep such an amplifier stable when driving the capacitance of a cable and the DUT. Further, even if switching proper resistors/compensation capacitors could be done, output voltage performance would not settle fast enough to meet drive capability and a 12 nanosecond risetime requirement. In addition, to meet the required settling times and accuracy on a 1 milliamp (low current) range, switches would need to be low capacitance and low leakage solid state relays. Such solid state relays can only switch on/off every 200 microseconds. The desire is to be able to drive the DUT up to 20 Mhz (e.g., stress cycles) then at certain points in the test, pause and make a current measurement (e.g., measure cycle) in less than 6 microseconds.

FIG. 4 illustrates an example block diagram of a circuit for current measurement with DUT isolation, according to some embodiments. As shown, the circuit can include all of the elements described above in reference to FIG. 3. In addition, as shown in FIG. 4, an isolation resistor, Risolation, can be placed between the sensing resistor and in series with the output cable to the DUT to stabilize the architecture. Note that Risolation also provides protection from short circuit on the output. In some instances, the isolation resistor can be a 50 ohm resistor. Such a value can be ideal to drive the cable impedance, however, any value greater than 0.5 ohms will remove the zero ohm output impedance to minimize load-line effects.

FIG. 5 illustrates an example block diagram of a circuit for current measurement with compensation for DUT isolation, according to some embodiments. As shown, the circuit can include all of the elements described above in reference to FIGS. 3 and 4. In addition, as shown in FIG. 5, to compensate the output impedance for the addition of the isolation resistor, U1 is added as an X1 buffer after the driver. U1 can be, in at least some instances, a high speed amplifier. In addition, a feedback loop for U1 is closed around the sensing resistor. Additionally, voltage output is the same as in FIG. 4 with X1 added. In addition, U2, which can also be a high speed amplifier, is added to the sensing resistor. Further, resistors R4 and R5 and capacitor Cpeak are added. In some instances, assuming equal resistance for resistors for R4 and R5, a current drop (e.g., due to load) generates a voltage across the sensing resistor. Further, if and/or when a resistance of the sensing resistor matches a resistance of the isolation resistor, a voltage drop will occur across the isolation resistor. The voltage across the sensing resistor, which is buffered by U2, is impressed upon R5 and a current of (Visense)/R5 is injected to resistor R4 which will raise a positive input into U1 by ((Visense)/R5)*R4. Hence when the resistance of resistor R4 matches the resistance of resistor R5, the voltage drop across the isolation resistor is compensated out. However, such positive feedback can lead to instability, thus capacitor Cpeak is included. Capacitor Cpeak can be adjustable. In some instances, adjustment of the capacitance value of Cpeak can be via a two bit adjustment. For example, a first capacitance value of capacitor Cpeak can correspond to a two bit value of “00”, a second capacitance value of capacitor Cpeak can correspond to a two bit value of “01”, a third capacitance value of capacitor Cpeak can correspond to a two bit value of “10”, and a fourth capacitance value of capacitor Cpeak can correspond to a two bit value of “11”. In some instances, capacitor Cpeak can lower a bandwidth of the positive feedback to ensure stability while compensating for the drop across the isolation resistor. Note that resistance values of the sensing resistor and the isolation resistor do not have to match. In such instances, differences in resistance values between the sensing resistor and the isolation resistor can be compensated for by a ratio of resistance values for resistor R5 and resistor R4. In addition, the circuit described in reference to FIG. 5 can be capable of driving high speed pulses and measuring current on a 10 milliamp range. In some instances, a resistance value of the isolation resistor can be based and/or depend, at least in part, on a length of a cable connecting the circuit to the DUT. For example, for shorter cables, the resistance value of the isolation resistor can be lower as compared to longer cable lengths (e.g., 20 ohms as compared to 50 ohms). One advantage of a lower resistance value of the isolation resistor is improved headroom and lower power demands.

FIG. 6 illustrates an example block diagram of a circuit for current measurement with compensation for DUT isolation and 1 milliamp and 10 milliamp ranges, according to some embodiments. As shown, the circuit can include all of the elements described above in reference to FIGS. 3, 4 and 5. In addition, as shown in FIG. 6, resistor R6, capacitor C1, and switch S1 can be added in series with the sensing resistor. The switch S1 can be a high speed switch, e.g., capable of switching in 10 nanoseconds. In some instances, the switch S1 can be a single pole, double throw (SPDT) switch. Further, a multiplexer can be added prior to the differential amplifier. In some instances, prior to sending one or more pulses, the multiplexer can be configured for measurements in the 1 milliamp range, however, the switch S1 can be closed and the one or more pulses can be sent to the DUT via the 10 milliamp circuit. Then, after proper settling time of an edge (e.g., after output voltage has settled), the switch S1 can be switched opened and current can be measured on the 1 milliamp range. Such a scheme can allow a load current to be re-routed to the proper sensing resistor without affecting the ability of the circuit to move.

FIG. 7 illustrates another example block diagram of a circuit for current measurement with compensation for DUT isolation and 1 milliamp and 10 milliamp ranges, according to some embodiments. As shown, the circuit can include all of the elements described above in reference to FIGS. 3, 4, 5, and 6. In addition, as shown in FIG. 7, a second switch, S2, can be added in series with the isolation resistor, Risolation. Similar to switch S1, switch S2 can be a high speed switch, e.g., capable of switching in 10 nanoseconds. In some instances, the switch S2 can be a single pole, double throw (SPDT) switch. In some instances, for measurement of currents of 100 microamps and below, the multiplexer can be configured for 100 uA-1 uA pathway. In addition, for measurements in the 100 microamp range (e.g., corresponding to resistor R7), solid state relays associated with the 10 microamp range (e.g., SSR2 corresponding to resistor R9) and 1 microamp range (e.g., SSR1 corresponding to resistor R8) can be switched on. Further, for measurements in the 10 microamp range, only the solid state relay associated with the 1 microamp range (e.g., SSR1) can be switched on and for the 1 microamp range, only the solid state relay associated with the 10 microamp range can be switched on. Note that these solid state relays can be pre-configured to a desired range (e.g., during a stress cycle and/or 200 microseconds prior to a desired measurement). In some instances, once one or more output pulses have settled, switch S2 can be switched to connect the isolation resistor to the I/V node. Load current can then be re-routed into the current measurement circuit, e.g., into amplifier U3. In some instances, amplifier U3 can be a high speed, low capacitance, complementary metal-oxide-semiconductor (CMOS) amplifier. The re-routing of the load current can create a voltage drop from the I/V node to 100 uA-1 u pathway proportional to 200 millivolts full scale/range. Note again the concept of switching after an output voltage has settled to eliminate degradation of high slew rate and fidelity of a pulse waveform. Note that switching after an output voltage has settled is critical so that all stray capacitance has been charged before engaging the low current circuit. After measurement is complete, the switch S2 can be switched back to normal (e.g., output voltage connected to the isolation resistor) before system moves to another level.

FIG. 8 illustrates an example block diagram of a circuit for current measurement with compensation for DUT isolation, 1 milliamp and 10 milliamp ranges, and tuning, according to some embodiments. As shown, the circuit can include all of the elements described above in reference to FIGS. 3, 4, 5, 6, and 7. In addition, as shown in FIG. 8, resistor R10 and capacitor Cslew are between the input (e.g., connection with the arbitrary waveform generator) and the driver. In some instances, capacitor Cslew can be adjustable. In some instances, whereas manipulation (e.g., adjustment) of a capacitance value of Cpeak can provide peaking to compensate for overdamped responses at the DUT, manipulating (e.g., adjustment) of a capacitance value of Cslew can aid in underdamped responses to allow obtainment of the flattest and fastest settling behaviors at the DUT. In some instances, adjustment of the capacitance value of Cslew can be via a two bit adjustment. For example, a first capacitance value of capacitor Cslew can correspond to a two bit value of “00”, a second capacitance value of capacitor Cslew can correspond to a two bit value of “01”, a third capacitance value of capacitor Cslew can correspond to a two bit value of “10”, and a fourth capacitance value of capacitor Cslew can correspond to a two bit value of “11”. Thus, the circuit illustrated in FIG. 8 can be configured to compensate for both overdamped responses and underdamped responses. In addition, amplifier U4 and resistor R11 are add to a measurement path for measurement of a voltage of the DUT. Further, a relay added prior to the connection for the oscilloscope can allow for current or voltage measurement at the oscilloscope.

FIG. 9 illustrates an example block diagram of a circuit for current measurement with compensation for DUT isolation, 1 milliamp and 10 milliamp ranges, tuning, and power supply, according to some embodiments. As shown, the circuit can include all of the elements described above in reference to FIGS. 3, 4, 5, 6, 7, and 8. In addition, as shown in FIG. 9, bootstrapped floating power supplies that move with the output voltage of the circuit are added. Note that for an output voltage range of ±10 volts at better than 12 nanosecond rise times dictates usage of a high speed current feedback amplifier for the gain section. However, such amplifiers have bias current levels of greater than 1 microamp and, as such, are not suitable for low current sensing. Further, junction field effect transistor (JFET) and CMOS amplifiers in the range of the targeted bandwidth and slew rate of the circuit only have a maximum power supply range of ±5 volts. Thus, the bootstrapped floating power supplies accommodate both types of amplifiers. Note for such a circuit to function properly, power supply rails must move in lock step with the output or risk overdriving the bootstrapped circuitry input protection diodes. Note further, at 12 nanosecond risetime for a 10 volt signal, a 6 nanosecond delay between power supply rails can develop a 5 volt error from the correct voltage. Thus, the circuit includes a second driver (e.g., Driver 2). The second driver can have the same gain and delay as the driver (e.g., Driver 1). In addition, the second driver can be a high speed driver. As shown, in some instances, the second driver can drive the boot node (e.g., “boot”) which can be a reference for floating ±5 volt power supplies powered by an isolated DC-DC converter and fed through a common mode filter to reduce noise. The DC-DC converter is powered by 24 volts delivered from the arbitrary waveform generator via an HDMI connection. Further, as shown, the circuitry in the dotted box can be powered by boot node referred supplies and includes reference planes, shielded can, and all measurement related components such as amplifiers, multiplexers, switches, solid state relays, and associated drivers. The front end of differential amplifier (e.g., “Diff Amp”) is also powered from the boot node. In this manner, all stray capacitances can be driven “or bootstrapped” out by the boot node. Additionally, digital control for the boot section is provided via opto-isolators except for a serial-peripheral interface (SPI) temperature sensor (not shown). Note that the second driver eliminates the need for the first driver to drive all the boot related stray capacitance in addition to the DUT and cable, thereby avoiding performance degradation of the first driver.

FIG. 10 illustrates an example block diagram of a circuit for current measurement with compensation for DUT isolation, 1 milliamp and 10 milliamp ranges, tuning, power supply, and calibration, according to some embodiments. As shown, the circuit can include all of the elements described above in reference to FIGS. 3, 4, 5, 6, 7, 8, and 9. In addition, as shown in FIG. 10, relay switches are added at the output to the oscilloscope (e.g., Relay) and at the output to the DUT (e.g., Output MUX). The output multiplexer in series with the output can maintain a guarded pathway from the output to the DUT. In addition, pathways to route the arbitrary waveform generator (AWG), the source measurement unit (SMU), e.g., output voltage from the circuit, and calibration loads (Cal Load) can be integrated into the output multiplexer. In some instances, during self-calibration, the SMU can calibrate voltage levels and current measurements. In some instances, this can include correcting for time/temperature errors incurred since a prior self-calibration. In addition, the SMU can be routed to the DUT to make precision DC I/V measurements and the arbitrary waveform generator can be routed to present a wide array of stimuli to the DUT. Additionally, as shown, a calibration pulse generator can be connected to the oscilloscope pathway and can be used to flatten a response of the oscilloscope and eliminate any thermal tails or mid frequency anomalies. The oscilloscope can then be used to eliminate the same errors from the arbitrary waveform generator by making use of digital filters in the arbitrary waveform generator. Finally, in addition to measuring current and voltage, the oscilloscope can also directly measure the output node via node Vmon (e.g., a voltage monitoring node emanating from the output multiplexer).

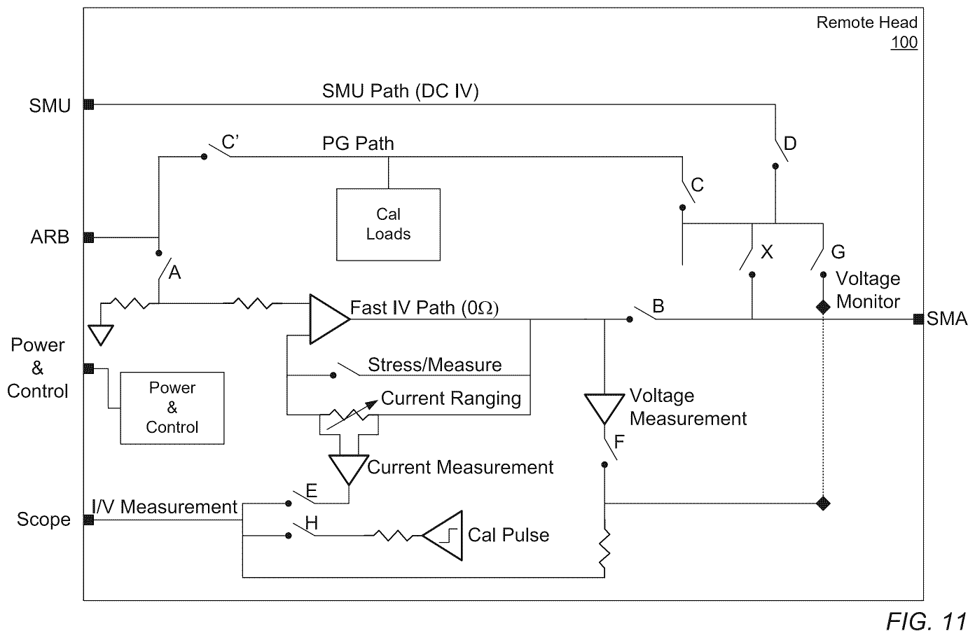

FIG. 11 illustrates an example of a simplified block diagram of a remote head for current and voltage measurements, according to some embodiments. Note that the remote head described in reference to FIG. 11 can be used in conjunction with the above described computer system 106 and/or server 104. For example, in some instances, software executing on computer system 106 and/or sever 104 can be used to control the remote head described in reference to FIG. 11. Note further, that in at least some instances, the functionalities of the circuits described in reference to FIGS. 3-10 can be included in the remote head described in reference to FIG. 11. As shown, remote head 100 can include one or more connections for a source measurement unit (SMU), an arbitrary waveform generator (ARB), power and control, and an oscilloscope (Scope). In addition, the remote head 100 can include an output (e.g., a subminiature version A (SMA)) for connection to a DUT. Further, as shown, the SMU, the ARB, and the oscilloscope can each have a path to the output connection, e.g., to the DUT. The remote head can include multiple switches to allow for these connections and associated functionalities. For example, the SMU can be routed to the output connection via switches D and either X or G. The ARB can be routed to the output connection via switches A and B, e.g., for zero impedance current measurement, DUT stress/measurement testing, or voltage measurement. Additionally, the ARB can be routed to the output connection via switches C′, C, and either X or G for calibration loading. The oscilloscope can be routed to assist with current measurement (e.g., via switch E), calibration (e.g., via switch H), and voltage measurement (e.g., via switch F). In some instances, the remote head 100 can be configured to amplify a voltage supplied by an ARB and drive the voltage to the output (e.g., to a DUT connected to the output). The range of the voltage driven to the output can vary up to ±10 volts. In addition, the remote head 100 can be configured to have a voltage rise time to an edge of less than 12 nanoseconds. In some instances, the remote head 100 can be configured to measure current, measure voltage, and or perform self-calibration. In addition, the remote head 100 can be configured to provide a monitoring voltage to the connection to the oscilloscope.

Embodiments of the present disclosure may be realized in any of various forms. For example, some embodiments may be realized as a computer-implemented method, a computer-readable memory medium, or a computer system. Other embodiments may be realized using one or more custom-designed hardware devices such as ASICs. Still other embodiments may be realized using one or more programmable hardware elements such as FPGAs.

In some embodiments, a non-transitory computer-readable memory medium may be configured so that it stores program instructions and/or data, where the program instructions, if executed by a computer system, cause the computer system to perform a method, e.g., any of the method embodiments described herein, or, any combination of the method embodiments described herein, or, any subset of any of the method embodiments described herein, or, any combination of such subsets.

In some embodiments, a device (e.g., a computer system 106) may be configured to include a processor (or a set of processors) and a memory medium, where the memory medium stores program instructions, where the processor is configured to read and execute the program instructions from the memory medium, where the program instructions are executable to implement any of the various method embodiments described herein (or, any combination of the method embodiments described herein, or, any subset of any of the method embodiments described herein, or, any combination of such subsets). The device may be realized in any of various forms.

Although the embodiments above have been described in considerable detail, numerous variations and modifications will become apparent to those skilled in the art once the above disclosure is fully appreciated. It is intended that the following claims be interpreted to embrace all such variations and modifications.

What is claimed is:

1. A circuit, comprising:
a first input;
a first resistor connected in series with the first input;
a first capacitor connected to an output of the first resistor, wherein the first capacitor is further connected to a ground;
a driver comprising a positive input, a negative input, and an output, wherein the positive input is connected in series with the first resistor;
a second resistor connected to the output of the driver;
a second capacitor in parallel with the second resistor; and
a feedback loop that comprises at least the second resistor and second capacitor; and
wherein the first capacitor is configured to compensate for an underdamped response of a waveform signal applied to the first input.

2. The circuit of claim 1,
wherein the second capacitor is configured to compensate for an overdamped response of the waveform signal applied to the first input.

3. The circuit of claim 1,
wherein a value of a capacitance of the first capacitor is adjustable.

4. The circuit of claim 3,
wherein the value of the capacitance of the first capacitor is adjustable via a two bit parameter.

5. The circuit of claim 4,
wherein a first capacitance value of the first capacitor can correspond to a two bit value of “00”, wherein a second capacitance value of the first capacitor can correspond to a two bit value of “01”, wherein a third capacitance value of the first capacitor can correspond to a two bit value of “10”, and wherein a fourth capacitance value of the first capacitor can correspond to a two bit value of “11”.

6. The circuit of claim 1,
wherein a value of a capacitance of the second capacitor is adjustable.

7. The circuit of claim 6,
wherein the value of the capacitance of the second capacitor is adjustable via a two bit parameter.

8. The circuit of claim 7,
wherein a first capacitance value of the second capacitor can correspond to a two bit value of “00”, wherein a second capacitance value of the second capacitor can correspond to a two bit value of “01”, wherein a third capacitance value of the second capacitor can correspond to a two bit value of “10”, and wherein a fourth capacitance value of the second capacitor can correspond to a two bit value of “11”.

9. A circuit, comprising:
a first port configured to accept a first analog signal from an arbitrary waveform generator;
a second port configured to interface with an oscilloscope;
a third port configured to interface with a device under test;
a fourth port configured to interface with a power supply and a controller;
first circuitry comprising at least a first driver configured to drive a second analog signal, based on the first analog signal, for voltage measurement and current measurement of the device under test; and
second circuitry comprising at least a second driver configured to drive a third analog signal to a boot node for powering the first circuitry in a bootstrapping manner.

10. The circuit of claim 9,
wherein the boot node operates as a floating power supply.

11. The circuit of claim 9,
wherein the third analog signal is based, at least in part, on the first analog signal.

12. The circuit of claim 9,
wherein the first circuitry further comprises a differential amplifier, and wherein stray capacitances in the first circuitry are driven out based on the boot node supplying power to a front end of the differential amplifier.

13. The circuit of claim 9,
wherein the first circuitry further comprises:
a first resistor connected in series with the first port wherein a positive input of the first driver is connected in series with the first resistor;
a first capacitor connected to an output of the first resistor, wherein the first capacitor is further connected to a ground;
a second resistor connected to an output of the first driver;
a second capacitor in parallel with the second resistor; and
a feedback loop connected to a negative input of the first driver that comprises at least the second resistor and second capacitor; and
wherein the first capacitor is configured to compensate for an underdamped response of a waveform signal applied to the first input.

14. The circuit of claim 13,
wherein the second capacitor is configured to compensate for an overdamped response of the waveform signal applied to the first input.

15. The circuit of claim 14,
wherein a value of a capacitance of the first capacitor is adjustable.

16. The circuit of claim 15,
wherein the value of the capacitance of the first capacitor is adjustable via a two bit parameter.

17. A remote test head comprising:
a first port configured to accept a first analog signal from an arbitrary waveform generator;
a second port configured to interface with an oscilloscope;
a third port configured to interface with a device under test;
a fourth port configured to interface with a power supply and a controller; and
first circuitry comprising at least a first driver and a differential amplifier, wherein the first driver is configured to drive a second analog signal, based on the first analog signal, for voltage measurement and current measurement of the device under test, and wherein the differential amplifier is connected to a ground and configured to translate a volage across the differential amplifier back to a measurement reference voltage.

18. The remote test head of claim 17, further comprising:
second circuitry comprising at least a second driver configured to drive a third analog signal to a boot node for powering the first circuitry in a bootstrapping manner.

19. The remote test head of claim 17,
wherein the first circuitry further comprises:
a first resistor connected in series with the first port wherein a positive input of the first driver is connected in series with the first resistor;
a first capacitor connected to an output of the first resistor, wherein the first capacitor is further connected to a ground;
a second resistor connected to an output of the first driver;
a second capacitor in parallel with the second resistor; and
a feedback loop connected to a negative input of the first driver that comprises at least the second resistor and second capacitor; and
wherein the first capacitor is configured to compensate for an underdamped response of a waveform signal applied to the first input.

20. The remote test head of claim 19,
wherein the second capacitor is configured to compensate for an overdamped response of the waveform signal applied to the first input.
